(19) United States
(12) Patent Application Publication
(10) Pub. No.: US 2005/0275062 A1
(43) Pub. Date: Dec. 15, 2005

(54) Semiconductor bare chip, method of recording ID information thereon, and method of identifying the same

(76) Inventor: Yuji Matsuda, Osaka (JP)

Correspondence Address: McDERMOTT WILL & EMERY LLP, 600 13th Street, N.W., Washington, DC, 20005-3096, US

(21) Appl. No.: 11/152,766

(22) Filed: Jun. 15, 2005

(30) Foreign Application Priority Data
Jun. 15, 2004 (JP) JP2004-176592

(51) Int. Cl. H01L 29/00

(52) U.S. Cl. 257/532

(57) ABSTRACT

An object is to provide a technique to facilitate an identification of a semiconductor bare chip. To achieve this object, the semiconductor bare chip includes a plurality of fuse elements f11 to f19 disposed, in a predetermined order, on a surface of a semiconductor substrate. ID information of the semiconductor bare chip is indicated by a combination of the order of the fuse elements and fusing status of the fuse elements, which indicate whether or not the respective fuse elements are fused.

### BACKGROUND OF THE INVENTION

(1) Field of the Invention

The present invention relates to a semiconductor bare chip, and more specifically, to a technique for identifying the semiconductor bare chip.

(2) Description of the Related Art

FIG. 1 is a schematic diagram illustrating a method of manufacturing common semiconductor integrated circuits (hereinafter referred to as ICs).

FIG. 2 is a flowchart illustrating the method of manufacturing the ICs shown in FIG. 1.

There are roughly two processes in the manufacturing of the ICs: a wafer fabrication and an assembly process.

Step S51: Preparing an un-processed bare wafer by the lot. In general, one lot of bare wafer 51 includes 25 to 50 wafers. In the manufacturing process of the ICs, a processing order to the wafers of the same lot, and a processing order to the ICs on the same wafer are maintained to be the same.

Step S52: Processing the bare wafer 51 in various ways, to manufacture a wafer 52 having a plurality of ICs formed thereon. The processing includes forming of thin films for transistors, implantation of impurities, etching, patterning, and wiring.

Step S53: Inspection of the ICs formed on the wafer 52.

Step S54: Dicing the wafer 52 so that each chip includes one IC, and obtaining a chip 53.

Step S55: Packaging the chip 53, thereby completing an IC package 54. The packaging includes bonding and packaging into a case.

Step S56: Final inspection of the IC package 54. After passing the final inspection, the IC package 54 is shipped.

In the manufacturing process of the ICs, ID information for identifying the chip, such as a lot number, a wafer number, and a chip number, are put to the package.

In recent years, downsizing of a main body of devices has increased the number of cases employing bare-chip mounting. When the bare-chip mounting is employed, there is no package to put the ID information. Japanese Laid-Open Patent Application No. H11-87198 discloses a technique such that a bare chip includes a non-volatile memory that is separately formed, and the ID information is recorded on the non-volatile memory to be read out when necessary.

However, the technique disclosed by No. H11-87198 has a problem that the ID information recorded in the non-volatile memory sometimes cannot be read out when something goes wrong with the bare chip, because the non-volatile memory can malfunction when the bare chip has a trouble. Without reading out the ID information, it is not possible to specify the lot number of the bare chip having the trouble. This results in a delay in taking effective measures such as replacing the bare chip in trouble or reinspecting bare chips of the same lot.

Moreover, adding on the non-volatile memory to the bare chip can increase the number of manufacturing steps as well as a chip area to a large-extent.

### SUMMARY OF THE INVENTION

An object of the present invention is to provide a technique to facilitate an identification of a semiconductor bare chip.

Another object of the present invention is to provide a technique to suppress an increase in the number of steps of manufacturing the semiconductor bare chip capable of facilitating the identification of the semiconductor bare chip.

Yet another object of the present invention is to provide a technique to suppress an increase in a chip area of the semiconductor bare chip capable of facilitating the identification of the semiconductor bare chip.

A semiconductor bare chip having ID information thereof according to the present invention comprises a semiconductor substrate, and an ID information recording member constituted by a plurality of pieces disposed in a predetermined order on the semiconductor substrate so as to be visible externally, each piece being alterable in appearance by processing, wherein the ID information recording member indicates the ID information by a combination of the appearance of each piece after the processing and the order of the pieces.

A semiconductor bare chip having ID information thereof according to the present invention comprises a semiconductor substrate, and an ID information recording member constituted by a plurality of pieces disposed, in a predetermined order, on the semiconductor substrate so as to be visible externally, the pieces having been selectively altered in appearance by processing, wherein the ID information recording member indicates the ID information by a combination of the appearance after the processing and the order of the pieces.

According to the above construction, the ID information recording member is visible externally, and the ID information may be obtained by visually checking the appearance of each piece after the processing and the order of the pieces. Thus, it is possible to facilitate the identification of the semiconductor bare chip compared to a semiconductor bare chip manufactured with a conventional technique.

The semiconductor bare chip according to the present invention may further comprise a plurality of pads disposed over the semiconductor substrate so as to correspond one-on-one to the pieces, wherein each piece has a first portion connected to a corresponding pad and a second portion connected to a ground electrode provided on the semiconductor substrate, and is alterable in appearance by fusing to cut the piece with a current supplied thereto.

According to the above construction, utilization of the pads facilitates fusing of the pieces with the current. Therefore, it is possible to suppress the increase in the number of steps of manufacturing the semiconductor bare chip capable of facilitating the identification of the semiconductor bare chip, compared to other processing techniques such as lasering and etching.

The semiconductor bare chip according to the present invention may be also such that each piece has an elongated shape constricted between the first and second portions that are at opposite ends of the piece.

According to the above construction, the constricted portion is preferentially fused. Thus, it is possible to avoid fusing at an unexpected portion.

The semiconductor bare chip according to the present invention may further comprise a main circuit formed on a main surface of the semiconductor substrate, wherein the pieces and the main circuit are made of a same material.

According to the above construction, any specific material for the pieces is not necessary, and thus it is possible to reduce the production cost of the semiconductor bare chip. Further, by forming the pieces at the same time when a part of the main circuit is formed, it is possible to suppress the increase in the number of steps of manufacturing the semiconductor bare chip capable of facilitating the identification of the semiconductor bare chip.

The semiconductor bare chip according to the present invention may further comprise a main circuit formed on a main surface of the semiconductor substrate, wherein the pieces are disposed over the main surface.

According to the above construction, positioning of the pieces is easy compared to a case in which the pieces are formed on a different surface from the surface on which the main circuit is formed. Further, by forming the pieces at the same time when a part of the main circuit is formed, it is possible to suppress the increase in the number of steps of manufacturing the semiconductor bare chip capable of facilitating the identification of the semiconductor bare chip.

A method of recording ID information of a semiconductor bare chip thereon according to the present invention is such a method including a plurality of pieces disposed on a semiconductor substrate so as to be visible externally, and comprising obtaining the ID information in a binary number, digits of the binary number corresponding one-on-one to the pieces; and selectively processing the pieces based on binary values of the corresponding digits.

According to the above construction, each piece can represent a binary value based on whether or not the piece is processed. Therefore, it is possible to facilitate the recording of the ID information compared to a case in which the processing to the pieces is contiguous or gradual.

The method of recording ID information according to the present invention may also be such that a main circuit is formed on a main surface of the semiconductor substrate, the pieces are fusible to be cut with a current supplied thereto, and the processing is performed by selectively supplying the current to the pieces with recording probes added to a probe card used in an inspection of the main circuit.

The method of recording ID information according to the present invention may also be such that a main circuit is formed on a main surface of the semiconductor substrate, the pieces are made of a plastic material, and the processing is performed by selectively pressing the pieces with recording probes added to a probe card used in an inspection of the main circuit.

According to the above construction, it is possible to record the ID information during a step of inspecting the main circuit. Therefore, it is possible to record the ID information without providing any additional step.

A method of identifying a semiconductor bare chip according to the present invention comprises a step of taking images each showing a form unique to each semiconductor bare chip, and recording the images on a recording medium in association with ID information used for identifying semiconductor bare chips, and a step of taking an image showing a form unique to a semiconductor bare chip to be identified, and comparing the unique form shown in the taken image with unique forms shown in the images recorded in the recording medium, thereby obtaining ID information of the semiconductor bare chip to be identified, wherein the semiconductor bare chip includes a fuse element that has been fused, and the unique form of each semiconductor bare chip is a serrated pattern on a surface of a fused section of the fuse element.

According to the above construction, it is possible to take an image of the serrated pattern externally. Therefore, the ID information can be obtained by taking the image of the serrated pattern even when something goes wrong with the semiconductor bare chip. This facilitates the identification of the semiconductor bare chip to a large extent in comparison with a conventional method.

The method of identifying the semiconductor bare chip according to the present invention may also be such that the semiconductor bare chip includes an image sensor circuit, and the fuse element is included in the image sensor circuit.

According to the above construction, it is not necessary to form an additional fuse element for identifying the semiconductor bare chip. Therefore, it is possible to suppress the increases in the number of manufacturing steps and the chip area of the semiconductor bare chip capable of facilitating the identification of the semiconductor bare chip.

A method of identifying a semiconductor bare chip according to the present invention comprises a step of taking images each showing a form unique to each semiconductor bare chip, and recording the images on a recording medium in association with ID information used for identifying semiconductor bare chips, and a step of taking an image showing a form unique to a semiconductor bare chip to be identified, and comparing the unique form shown in the taken image with unique forms shown in the images recorded in the recording medium, thereby obtaining ID information of the semiconductor bare chip to be identified, wherein the semiconductor bare chip is obtained by dicing a wafer, and the form unique to each semiconductor bare chip is a serrated pattern on a diced surface of the semiconductor bare chip.

According to the above construction, it is possible to take an image of the serrated pattern externally. Therefore, the ID information can be obtained by taking the image of the serrated pattern even when something goes wrong with the semiconductor bare chip. This facilitates the identification of the semiconductor bare chip to a large extent in comparison with the conventional method. Further, the serrated pattern here is not formed specifically for identifying the semiconductor bare chip. Thus, it is possible to suppress the increases in the number of manufacturing steps and the chip area of the semiconductor bare chip capable of facilitating the identification of the semiconductor bare chip.

### BRIEF DESCRIPTION OF THE DRAWINGS

These and the other objects, advantages and features of the invention will become apparent from the following description thereof taken in conjunction with the accompanying drawings which illustrate a specific embodiment of the invention.

In the drawings:

FIG. 1 is a schematic view illustrating a common manufacturing method of semiconductor ICs;

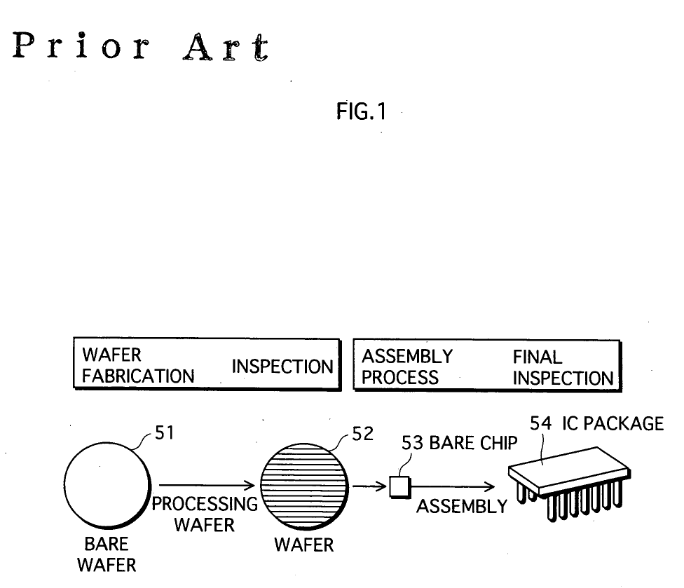

FIG. 2 is a flowchart showing the manufacturing method illustrated in FIG. 1;

FIG. 3 is a schematic plan view of a semiconductor bare chip according to a first embodiment;

FIG. 4 illustrates a connection between the semiconductor bare chip and a probe card;

FIG. 5 is a block diagram illustrating a schematic construction of a wafer inspecting apparatus;

FIG. 6 is a flowchart showing a method of recording ID information on the semiconductor bare chip according to the first embodiment;

FIG. 7 illustrates a connection between the semiconductor bare chip and the probe card according to a second embodiment;

FIG. 8 is a schematic view illustrating a method of identifying the semiconductor bare chip according to a third embodiment;

FIG. 9 is a flowchart showing the method of identifying the semiconductor bare chip according to the third embodiment; and

FIG. 10 is a schematic view illustrating a method of identifying the semiconductor bare chip according to a fourth embodiment.

### DESCRIPTION OF THE PREFERRED EMBODIMENTS

The following describes preferred embodiments of the present invention in detail with reference to the drawings.

### First Embodiment

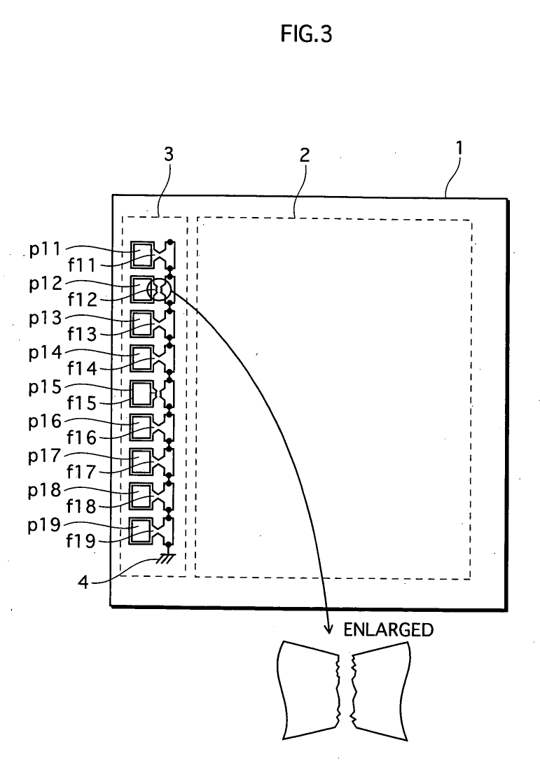

FIG. 3 is a schematic plan view of a semiconductor bare chip according to a first embodiment.

The semiconductor bare chip is constituted by a semiconductor substrate 1 and an IC formed thereon. A main circuit is formed in a region 2 of a main surface of the semiconductor substrate 1, and fuse elements f11 to f19 and pads p11 to p19 are disposed in a predetermined order in a region 3 of the main surface of the substrate 1.

In the first embodiment, the 9 fuse elements constitute an ID information recording member, which indicates ID information of the semiconductor bare chip by whether or not each fuse element is fused (fusing status) and the order of the 9 fuse elements.

Each fuse element represents a binary value based on whether or not the fuse element is fused. With the 9 fuse elements, it is possible to represent 9-bit ID information. A user reads the ID information visually by seeing the fusing status and the order of the 9 fuse elements.

Correspondence between digits of the ID information and the fuse elements, and between the fusing status and the binary values can be any kind, as long as the correspondence is commonly determined for every semiconductor bare chip. An example shown in FIG. 3 represents the ID information “101101111”, for instance, provided that the fuse element f11 represents the highest digit and the fuse element f19 represents the lowest digit, and each fuse element represents “0” when fused.

The fuse elements have an elongated shape with one end connected to the corresponding pad and the other end connected to a ground electrode 4. A part between the both ends is constricted. With such a construction, it becomes easier to fuse the fuse elements at the constricted part, rather than other parts, and thus fusing at an unexpected part can be avoided.

It is preferable that a material for the fuse elements is the same as a material for the main circuit. With this construction, it is possible to reduce the production cost of the semiconductor bare chip. For example, polysilicon, aluminum, copper, and tungsten may be used as the material for the fuse elements.

The fuse elements are disposed on the main surface on which the main circuit is formed, and can be formed in the same step in which the main circuit is formed. By this, it is possible to reduce the production cost of the semiconductor bare chip.

As described above, the semiconductor bare chip according to the first embodiment includes the fuse elements for recording the ID information that are formed on the main surface of the semiconductor substrate 1. These fuse elements are visible externally from outside, and accordingly, it is possible for the user to obtain the ID information even when the semiconductor bare chip has a trouble. Thus, the identification of the semiconductor bare chip can be facilitated to a large extent.

Further, the fuse elements can be formed with less manufacturing steps than forming a non-volatile memory. Therefore, it is possible to reduce the production cost of the semiconductor bare chip to a large extent.

Next, the following describes a method of recording the ID information on the semiconductor bare chip.

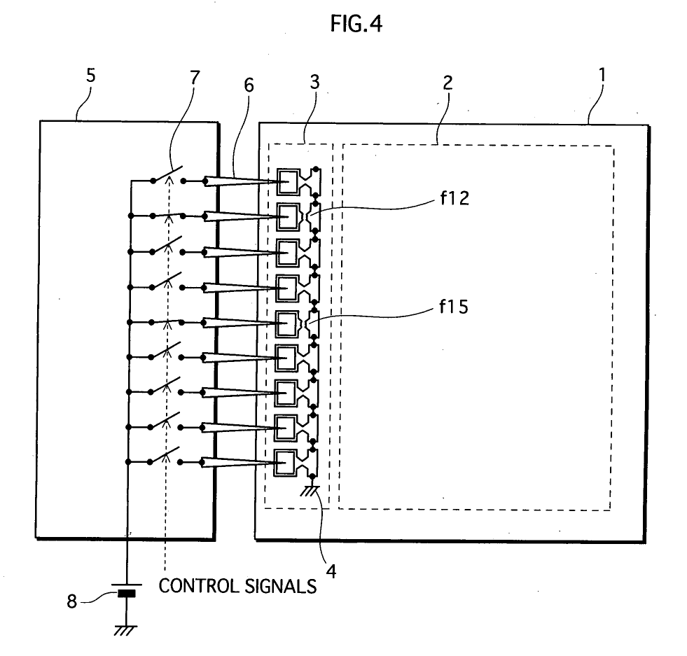

FIG. 4 illustrates an example of a connection between the semiconductor bare chip and a probe card.

A probe card 5 is provided with components for inspecting the main circuit and for recording the ID information. The probe card 5 illustrated in FIG. 4 only shows the component for recording the ID information. The recording component includes probes 6 and switches 7.

The probes 6 are in touch with the respective pads. The switches 7 are inserted in respective wirings that connect between the probes 6 and a power source 8, and turned on and off according to control signals transmitted from a tester, which will be described later.

With such a construction, when any of the switches 7 is turned on, the corresponding fuse element is supplied with a current, which fuses the element in turn. In the example shown in FIG. 4, the fuse elements f12 and f15 are fused.

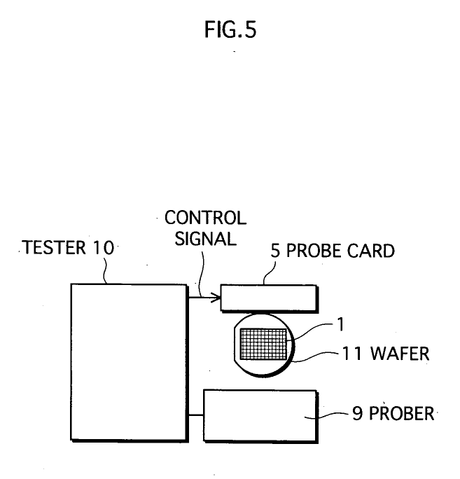

FIG. 5 is a block diagram illustrating a schematic construction of a wafer inspecting apparatus.

The wafer inspecting apparatus is provided with the probe card 5, a prober 9, and a tester 10.

The prober 9 includes a base for placing a wafer 11. By moving the base, the probes of the probe card 5 are brought into contact with the pads formed on the wafer 11. The tester 10 transmits the control signals to the probe card 5.

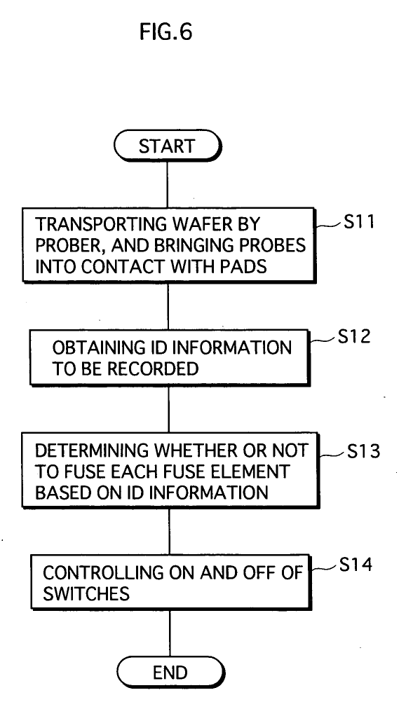

FIG. 6 is a flowchart showing the method of recording the ID information on the semiconductor bare chip according to the first embodiment.

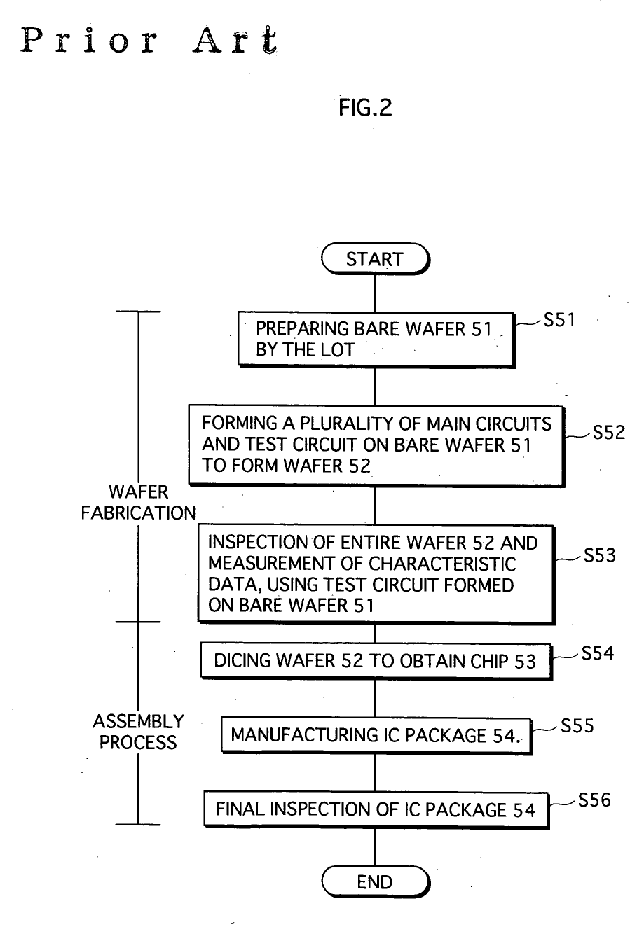

The recording of the ID information is performed during a wafer inspection step (See Step S53 in FIG. 2). Here, the wafer 11 is already placed on the base of the prober 9.

Step S11: the prober 9 transports the wafer 11, and brings the probes into contact with the respective pads.

Step S12: the tester 10 obtains the ID information representing “101101111” to be recorded.

Step S13: the tester 10 determines whether or not to fuse the fuse elements (fusing necessity) based on the binary values of the respective digits of the obtained ID information. Whether or not to fuse is determined according to the predetermined correspondence between the digits of the ID information and the fuse elements, and between the fusing status and the binary digits. In the present embodiment, the fuse elements f12 and f15 are set to be “fuse”, and the remaining fuse elements are set to be “no-fuse”.

Step S14: the tester 10 generates the control signals according to the determined fusing necessity. The control signals turn on the switches for the fuse elements to be fused, and turn off the switches for the fuse elements not to be fused. The tester 10 transmits the generated control signals to the probe card 5. Each switch is controlled to be turned on and off according to the transmitted control signals. As a result, the fuse elements f12 and f15 are fused.

### Second Embodiment

A second embodiment is different from the first embodiment in that the ID information is recorded by pressing the ID information recording member. The features common to the first embodiment are not described below.

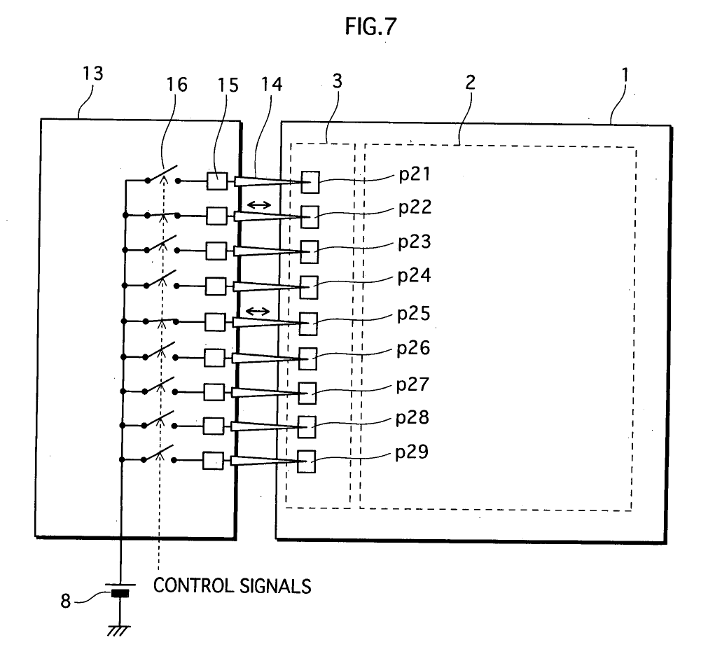

FIG. 7 illustrates a connection between the semiconductor bare chip and the probe card according to the second embodiment.

Pads p21 to p29 are disposed in the region 3 of the main surface of the substrate 1 of the semiconductor bare chip.

In the second embodiment, the 9 pads constitute the ID information recording member, which indicates the ID information of the semiconductor bare chip by whether or not each pad is marked (marking status) and the order of the 9 pads.

A probe card 13 is provided with a component for recording the ID information, which includes probes 14, actuators 15, and switches 16.

The probes 14 are supported by the actuators 15. When the power is supplied, the actuators 15 move the probes 14 so that the probes press the respective pads. The switches 16 are inserted in respective wirings that connect between the actuators 15 and the power source 8, and turned on and off according to the control signals transmitted from the tester.

Each pad represents a binary value based on whether or not the pad is marked. A user reads the ID information visually by seeing the marking status and the order of the 9 pads.

A material for the pads may be any kind of plastic material, although it is preferable that the material for the pads is the same as the material for the main circuit. With this construction, it is possible to reduce the production cost of the semiconductor bare chip. For example, a metal wiring material may be used as the material for the pads.

The recording of the ID information is performed during the wafer inspection step as in the first embodiment. A difference from the first embodiment is that the actuators 15 press the pads p22 and p25 with the probes 14. As a result of the pressing, the pads p22 and p25 are marked.

The pressing gives less damage to surroundings of a target of the process than the fusing. This allows a pitch between the pads narrower, and thus it is possible to downsize the semiconductor bare chip.

### Third Embodiment

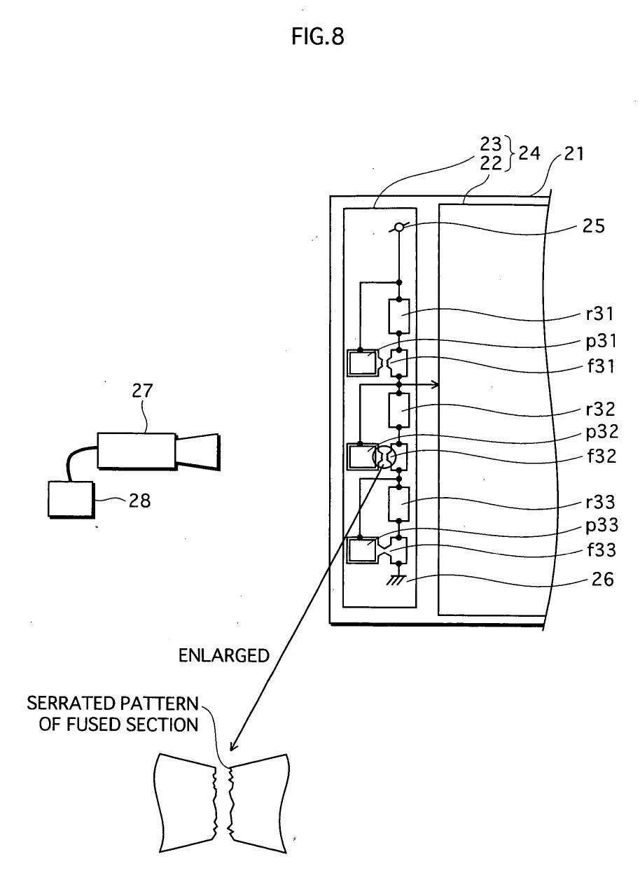

FIG. 8 is a schematic view illustrating a method of identifying the semiconductor bare chip according to a third embodiment.

The semiconductor bare chip is constituted by a semiconductor substrate 21 and an image sensor circuit 24 formed thereon. An imaging circuit 22 and a voltage regulator circuit 23 are formed on a main surface of the semiconductor substrate 21. The voltage regulator circuit 23 includes fuse elements f31 to f33, pads p31 to p33, and resistive elements r31 to r33.

A characteristic part of the third embodiment lies in that a serrated pattern on a fused section of the fuse elements is used to identify the semiconductor bare chip. In microscopic view, the serrated pattern is unique to each semiconductor bare chip, and thus can be utilized in the identification of the semiconductor bare chip. A camera 27 takes an image of the serrated pattern of each semiconductor bare chip and records data of the images in a recording medium 28.

The image sensor circuit 24 includes the voltage regulator circuit 23 as standard equipment. The voltage regulator circuit 23 is a circuit to regulate a voltage supplied to the imaging circuit 22, and is provided with the fuse elements for adjusting a value of resistance. Because the fuse elements are utilized to identify the semiconductor bare chip, it is not necessary to provide any specific ID information recording member.

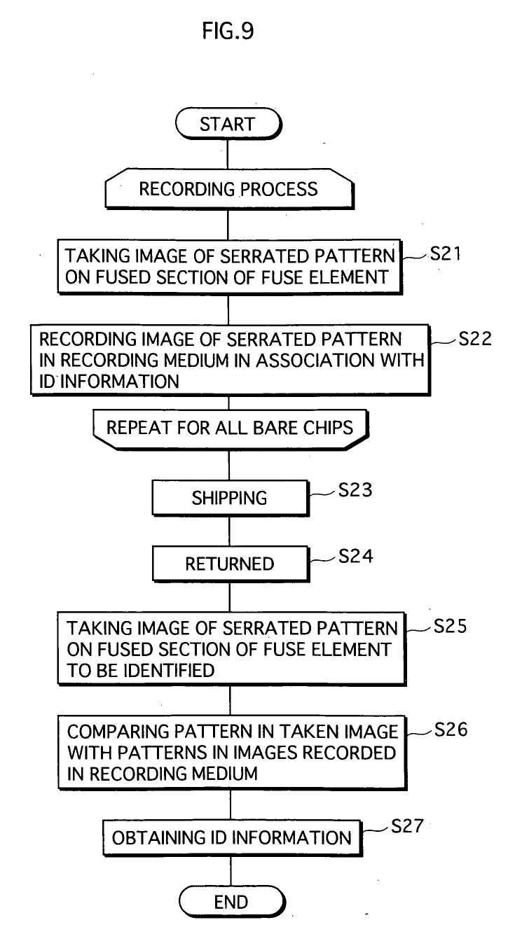

FIG. 9 is a flowchart showing the method of identifying the semiconductor bare chip according to the third embodiment.

An example taken is a case of specifying a lot number of a semiconductor bare chip that has been returned after the shipping.

Here, the fuse elements disposed on the semiconductor bare chip have already been fused as appropriate.

Step S21: Searching a fuse element that has been fused on the semiconductor bare chip, and taking an image of the serrated pattern on the fused section of the fuse element. How to handle cases in which more than one fuse element is fused can be any way, as long as every semiconductor bare chip is handled in the same way. For example, images of an entire serrated pattern can be taken. It is also possible to select a target for taking an image according to predetermined rules, and take an image of the selected target.

Step S22: Recording the image of the serrated pattern on the recording medium in association with the ID information.

The above steps S21 and S22 are performed to all semiconductor bare chips before shipping.

Step S23: Shipping the semiconductor bare chips.

Step S24: A semiconductor bare chip being returned.

Step S25: Searching the fuse element that is fused on the returned semiconductor bare chip, and taking an image of the serrated pattern on the fused section of the fuse element.

Step S26: Comparing the serrated pattern in the taken image with a plurality of serrated patterns in the images recorded in the recording medium. The comparing is performed using a common pattern matching method.

Step S27: If the serrated pattern in the taken image matches one of the serrated patterns in the images recorded in the recording medium, reading out ID information recorded in association with the matched serrated pattern. Consequently, it is possible to specify the lot number.

As described above, the method of identifying the semiconductor bare chip according to the third embodiment utilizes the fuse element disposed on the main surface of the semiconductor substrate 21. These fuse elements are visible externally, and accordingly, it is possible for the user to obtain the ID information even when the semiconductor bare chip has a trouble. Thus, the identification of the semiconductor bare chip can be facilitated to a large extent.

Further, the image sensor circuit 24 is provided with the fuse elements as standard equipment. Therefore, it is possible to suppress the increase in the number of steps of manufacturing the semiconductor bare chip, because any additional ID information recording member does not have to be provided in order to identify the semiconductor bare chip.

### Fourth Embodiment

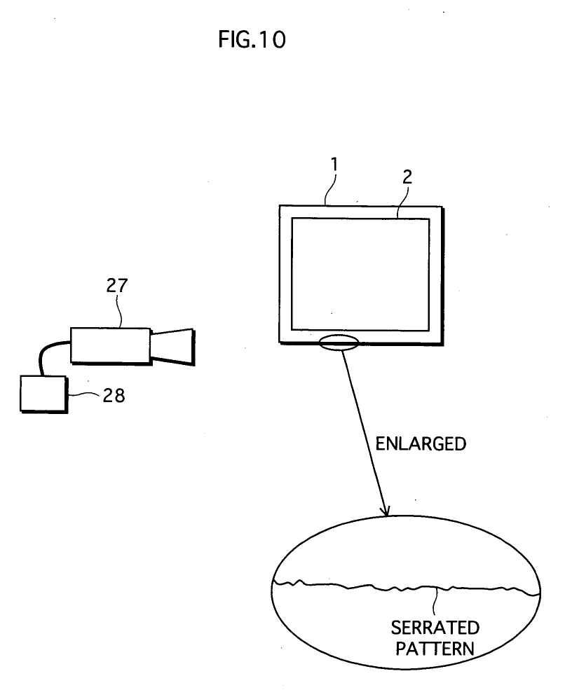

FIG. 10 is a schematic view illustrating a method of identifying the semiconductor bare chip according to a fourth embodiment.

The fourth embodiment is different from the third embodiment in that a side surface (diced surface) of the semiconductor bare chip is utilized as a form unique to the semiconductor bare chip. The features common to the third embodiment are not described below.

The semiconductor bare chip is obtained by dicing a wafer, and the diced surface is also obtained by the dicing of the wafer at the same time. The dicing of the wafer is performed using a dicing saw.

A characteristic part of the fourth embodiment lies in that the serrated pattern on the diced surface of the semiconductor bare chip is used to identify the semiconductor bare chip. In microscopic view, the serrated pattern is unique to each semiconductor bare chip, and thus can be utilized in the identification of the semiconductor bare chip. A camera 27 takes an image of the serrated pattern of each semiconductor bare chip and records data of the images on a recording medium 28. A target part of the semiconductor bare chip to be taken by the camera 27 can be any part, as long as the part is commonly set to every semiconductor bare chip. For example, an image of an entire circumference of a semiconductor bare chip can be taken. For another example, an image of a predetermined part of a semiconductor bare chip can be taken.

As described above, the method of identifying the semiconductor bare chip according to the fourth embodiment utilizes the side surface of the semiconductor bare chip. The side surface is visible externally, and accordingly, it is possible for the user to obtain the ID information even when the semiconductor bare chip has a trouble. Thus, the identification of the semiconductor bare chip can be facilitated to a large extent.

Further, the side surface is not anything especially provided for the semiconductor bare chip for its identification. Therefore, it is possible to suppress the increase in the number of steps of manufacturing the semiconductor bare chip.

### MODIFIED EXAMPLES

(1) In the first and second embodiments, fusing and pressing are cited as examples of the processing. However, the present invention is not restricted to these examples, and lasering may be utilized as an alternative. When the fuse elements are fused with the lasering, the pads and wirings are not necessary, because supplying the current is not required.

(2) In the first and second embodiments, the components that constitute the ID information recording member are disposed one-dimensionally. However, the present invention is not restricted to this example, and the components may be disposed two-dimensionally.

(3) In the first and second embodiments, no extra component is positioned over the ID information recording member that is on the substrate. However, the present invention is not restricted to such an example if the ID information recording member is visible externally from outside. For example, the ID information recording member may be covered by a translucent material.

(4) The third embodiment describes the circuit that includes the fuse element as standard equipment. However, the present invention is not restricted to this example, and the fuse element may be provided specifically in order to identify the semiconductor bare chip.

(5) The third embodiment describes the image sensor circuit. However, the present invention is not restricted to this example, and it is possible to obtain the same effects with any circuit if the circuit includes the fuse element as standard equipment.

Although the present invention has been fully described by way of examples with reference to the accompanying drawings, it is to be noted that various changes and modifications will be apparent to those skilled in the art. Therefore, unless otherwise such changes and modifications depart from the scope of the present invention, they should be construed as being included therein.

1. A semiconductor bare chip having ID information thereof, comprising:
a semiconductor substrate; and
an ID information recording member constituted by a plurality of pieces disposed in a predetermined order on the semiconductor substrate so as to be visible externally, each piece being alterable in appearance by processing, wherein
the ID information recording member indicates the ID information by a combination of the appearance of each piece after the processing and the order of the pieces.

2. A semiconductor bare chip according to claim 1, further comprising:
a plurality of pads disposed over the semiconductor substrate so as to correspond one-on-one to the pieces, wherein
each piece has a first portion connected to a corresponding pad and a second portion connected to a ground electrode provided on the semiconductor substrate, and is alterable in appearance by fusing to cut the piece with a current supplied thereto.

3. A semiconductor bare chip according to claim 2, wherein
each piece has an elongated shape constricted between the first and second portions that are at opposite ends of the piece.

4. A semiconductor bare chip according to claim 1, further comprising:
a main circuit formed on a main surface of the semiconductor substrate, wherein
the pieces and the main circuit are made of a same material.

5. A semiconductor bare chip according to claim 1, further comprising:
a main circuit formed on a main surface of the semiconductor substrate, wherein
the pieces are disposed over the main surface.

6. A method of recording ID information of a semiconductor bare chip on the semiconductor bare chip including a plurality of pieces disposed on a semiconductor substrate so as to be visible externally, the method comprising:
obtaining the ID information in a binary number, digits of the binary number corresponding one-on-one to the pieces; and
selectively processing the pieces based on binary values of the corresponding digits.

7. A method of recording ID information according to claim 6, wherein
a main circuit is formed on a main surface of the semiconductor substrate,
the pieces are fusible to be cut with a current supplied thereto, and
the processing is performed by selectively supplying the current to the pieces with recording probes added to a probe card used in an inspection of the main circuit.

8. A method of recording ID information according to claim 6, wherein
a main circuit is formed on a main surface of the semiconductor substrate,
the pieces are made of a plastic material, and
the processing is performed by selectively pressing the pieces with recording probes added to a probe card used in an inspection of the main circuit.

9. A method of identifying a semiconductor bare chip, comprising:
a step of taking images each showing a form unique to each semiconductor bare chip, and recording the images on a recording medium in association with ID information used for identifying semiconductor bare chips; and
a step of taking an image showing a form unique to a semiconductor bare chip to be identified, and comparing the unique form shown in the taken image with unique forms shown in the images recorded in the recording medium, thereby obtaining ID information of the semiconductor bare chip to be identified, wherein
the semiconductor bare chip includes a fuse element that has been fused, and the unique form of each semiconductor bare chip is a serrated pattern on a surface of a fused section of the fuse element.

10. A method of identifying a semiconductor bare chip according to claim 9, wherein
the semiconductor bare chip includes an image sensor circuit, and
the fuse element is included in the image sensor circuit.

11. A method of identifying a semiconductor bare chip, comprising:
a step of taking images each showing a form unique to each semiconductor bare chip, and recording the images on a recording medium in association with ID information used for identifying semiconductor bare chips; and
a step of taking an image showing a form unique to a semiconductor bare chip to be identified, and comparing the unique form shown in the taken image with unique forms shown in the images recorded in the recording medium, thereby obtaining ID information of the semiconductor bare chip to be identified, wherein
the semiconductor bare chip is obtained by dicing a wafer, and the form unique to each semiconductor bare chip is a serrated pattern on a diced surface of the semiconductor bare chip.

12. A semiconductor bare chip having ID information thereof, comprising:
a semiconductor substrate;
an ID information recording member constituted by a plurality of pieces disposed, in a predetermined order, on the semiconductor substrate so as to be visible externally, the pieces having been selectively altered in appearance by processing, wherein
the ID information recording member indicates the ID information by a combination of the appearance after the processing and the order of the pieces.
